(19) United States
(12) Patent Application Publication
(10) Pub. No.: US 2024/0188248 A1
(43) Pub. Date: Jun. 6, 2024

(54) ROOFTOP REFRIGERATION SYSTEM AND CONTAINER DATA CENTER

(71) Applicant: Hebei Qinhuai Data Co., Limited., Zhangjiakou City, Hebei Province (CN)

(72) Inventors: Binghua ZHANG, Zhangjiakou City (CN); Mingjiang LI, Zhangjiakou City (CN)

(21) Appl. No.: 18/520,077

(22) Filed: Nov. 27, 2023

(30) Foreign Application Priority Data
Dec. 2, 2022 (CN) 202211540524.0

(51) Int. Cl. H05K 7/20

(52) U.S. Cl. CPC H05K 7/20009

(57) ABSTRACT

The present disclosure discloses a rooftop refrigeration system and a container data center. The rooftop refrigeration system at least includes a box body, a component to be cooled, a barrier, and a refrigeration element. The box body is provided with an accommodating cavity. The component to be cooled, the barrier and the refrigeration element are installed in the accommodating cavity. The barrier is arranged on a top surface of the component to be cooled, the barrier and the component to be cooled divide the accommodating cavity into a hot runner and a cold runner, and a plurality of through holes are provided on a side surface of the barrier. A plurality of the refrigeration elements are provided, air inlets of the refrigeration elements are communicated with the through holes one to one, and air outlets of the refrigeration elements are communicated with the cold runner.

### CROSS REFERENCE TO RELATED APPLICATION

This application claims priority to Chinese Patent Application No. 202211540524.0, titled “ROOFTOP REFRIGERATION SYSTEM AND CONTAINER DATA CENTER” and filed to the China National Intellectual Property Administration on Dec. 2, 2022, the entire contents of which are incorporated herein by reference.

### TECHNICAL FIELD

The present disclosure relates to the field of a data center, and more particularly, to a rooftop refrigeration system and a container data center.

### BACKGROUND

A container data center refers to a data center formed in a modular way, where a container is used as a carrier, and server components are loaded in the container.

According to a refrigeration mode of servers in an existing container data center, typically inter-column air conditioners are installed in the container, and the inter-column air conditioners and the servers are arranged at intervals side by side, to ensure refrigeration effects to the servers. However, due to limited internal space of the container, the above mode where the inter-column air conditioners and the servers are arranged at intervals side by side may naturally lead to a decrease in the number of the servers inside a single container, resulting in a decrease in corresponding computing capacity.

### SUMMARY

An objective of the present disclosure is to provide a rooftop refrigeration system and a container data center, to increase number of servers arranged in a container.

To achieve the above objective, one aspect of the present disclosure provides a rooftop refrigeration system, which at least includes a box body, a component to be cooled, a barrier, and a refrigeration element. The box body is provided with an accommodating cavity. The component to be cooled, the barrier and the refrigeration element are installed in the accommodating cavity. The barrier is arranged on a top surface of the component to be cooled, the barrier and the component to be cooled divide the accommodating cavity into a hot runner and a cold runner, and a plurality of through holes are provided on a side surface of the barrier. A plurality of the refrigeration elements are provided, air inlets of the refrigeration elements are communicated with the through holes one to one, and air outlets of the refrigeration elements are communicated with the cold runner.

To achieve the above objective, another aspect of the present disclosure also provides a container data center, which at least includes the rooftop refrigeration system. The box body is a container, and the component to be cooled is a server unit.

As can be seen, according to the technical solutions provided by the present disclosure, the barrier is arranged on the top surface of the component to be cooled, the barrier and the component to be cooled divide the accommodating cavity into the hot runner and the cold runner, and a plurality of through holes are provided on the side surface of the barrier. Air inlets of the refrigeration elements are communicated with the through holes one to one, and air outlets of the refrigeration elements are communicated with the cold runner. The refrigeration element discharges cold air into a cold channel, the cold air passes through the component to be cooled for heat exchange to form hot air flowing into a hot channel, and the hot air in the hot channel enters the refrigeration element through the through hole for heat exchange. In this way, a refrigeration cycle is formed, to ensure refrigeration effects of the component to be cooled. Furthermore, the refrigeration element is positioned above the component to be cooled, which can increase the number of the servers arranged in the container and thus increase computing capacity of the container data center compared with the existing mode where the refrigeration elements and the servers are arranged at intervals side by side.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic top view of a rooftop refrigeration system according to an embodiment of the present disclosure;

FIG. 2 is an A-A sectional view of FIG. 1;

FIG. 3 is a B-B sectional view of FIG. 1;

FIG. 4 is an enlarged view of Part A of FIG. 3;

FIG. 5 is a schematic axonometric drawing of a telescopic adjusting component according to an embodiment of the present disclosure; and

FIG. 6 is a schematic structural diagram of a telescopic adjusting component according to another embodiment of the present disclosure.

Reference numerals in the drawings: box body 1; accommodating cavity 11; hot runner 111; cold runner 112; cushion space 12; component to be cooled 2; barrier 3; through hole 31; refrigeration element 4; supporting mechanism 5; supporting member 51; fixing member 52; slide bar 53; spring 54; adjusting screw rod 55; and baffle 56.

### DETAILED DESCRIPTION

Detailed description of implementations of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

According to a refrigeration mode of servers in an existing container data center, typically inter-column air conditioners are installed in the container, and the inter-column air conditioners and the servers are arranged at intervals side by side, to ensure refrigeration effects to the servers. However, due to limited internal space of the container, the above mode where the inter-column air conditioners and the servers are arranged at intervals side by side may naturally lead to a decrease in the number of the servers inside a single container, resulting in a decrease in corresponding computing capacity.

In addition, existing inter-column air conditioners generally are connected to the container by means of screw bolt assembly, which is inconvenient for disassembly and maintenance in daily maintenance process of the inter-column air conditioners.

Therefore, it is urgent how to improve an internal refrigeration structure of the container and increase the number of the servers in the container to facilitate the follow-up maintenance.

The technical solutions in the embodiments of the present disclosure will be clearly and completely described with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

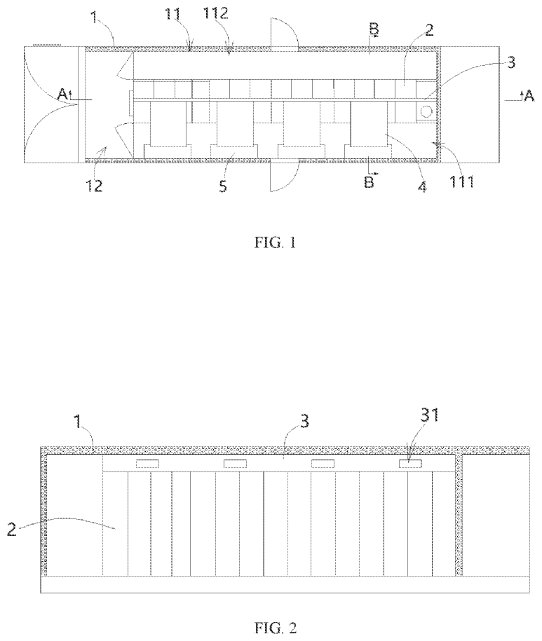

In an implementable embodiment, referring to FIGS. 1 to 3, a rooftop refrigeration system may at least include a box body 1, a component to be cooled 2, a barrier 3, and a refrigeration element 4. The box body 1 is provided with an accommodating cavity 11, which is configured to accommodate the component to be cooled 2, the barrier 3, and the refrigeration element 4. The barrier 3 is arranged on a top surface of the component to be cooled 2, the barrier 3 and the component to be cooled 2 divide the accommodating cavity 11 into a cold runner 111 and a hot runner 112, and a plurality of through holes 31 are provided on a side surface of the barrier 3. In this way, air above the component to be cooled 2 may be communicated through the through holes 31. A plurality of refrigeration elements 4 may be provided, where air inlets of the refrigeration elements 4 are communicated with the through holes 31 one to one, and air outlets of the refrigeration elements 4 are communicated with the cold runner 111.

In this embodiment, number of the refrigeration elements 4 is equal to that of the through holes 31, such that when the air inlets of the refrigeration elements 4 are communicated with the through holes 31 one to one, hot air in the hot runner 112 can only flow into the cold runner 111 through the refrigeration elements 4. In this way, the refrigeration elements 4 can refrigerate the hot air flowing through them. The plurality of through holes 31 may be arranged in a linear array along a length direction of the barrier 3, and correspondingly, the refrigeration elements 4 are arranged in a linear array along a length direction of the component to be cooled 2. In this way, cold air discharged through the plurality of refrigeration elements 4 can uniformly exchange heat to the component to be cooled 2, such that the refrigeration effects to the component to be cooled 2 can be improved.

In practical use, the component to be cooled 2 refers to a component that needs to be cooled, such as a server cabinet, an array cabinet and an internal electric source, etc. The refrigeration element 4 may be a cabinet containing an evaporator, where a fan, a coil and the like may be provided in the cabinet to accelerate air motion. Correspondingly, a compressor, a condenser and an expansion valve may also be installed outside the box body 1. The evaporator, the compressor, the condenser and the expansion valve are connected in series to form a refrigeration loop, thus forming a refrigeration cycle.

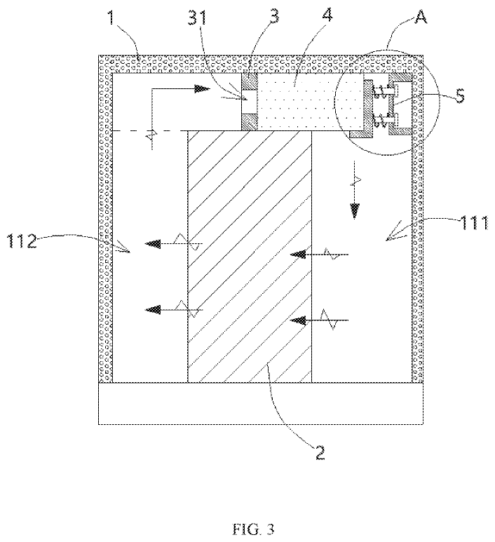

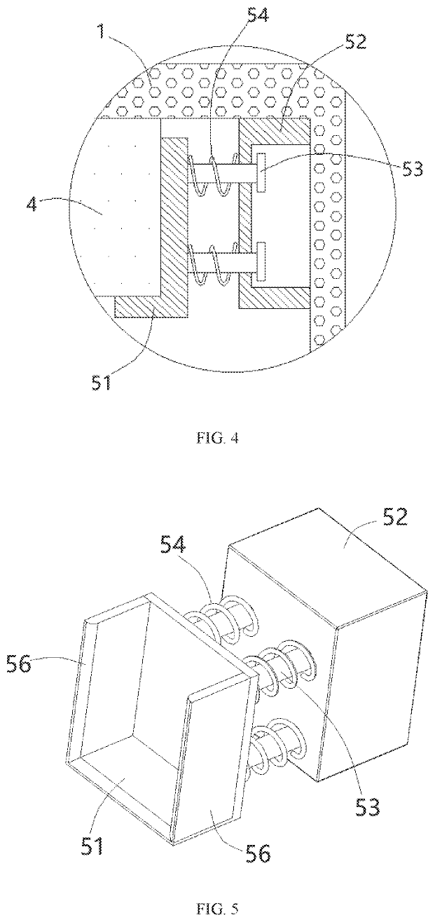

In an implementable embodiment, as shown in FIG. 3 and FIG. 4, one end of the refrigeration element 4 is placed on the top surface of the component to be cooled 2, and the other end of the refrigeration element 4 is connected to the box body 1 through a supporting mechanism 5, such that the refrigeration element 4 is installed above the component to be cooled 2. In this way, the refrigeration element 4 is positioned above the component to be cooled 2, which can increase the number of the servers arranged in the container and thus increase the computing capacity of the container data center compared with the existing mode where the refrigeration elements and the servers are arranged at intervals side by side.

It is to be noted that an air outlet of the supporting mechanism 5 may be arranged downward to prevent the supporting mechanism 5 from blocking the air out of the refrigeration element 4. In one embodiment, a guide duct may be provided at the air outlet of the supporting mechanism 5, such that a direction of the air outlet of the supporting mechanism 5 can be changed through the guide duct.

Further, the supporting mechanism 5 may at least include a supporting member 51, a fixing member 52, and a telescopic adjusting component. A cross section of the supporting member 51 is L-shaped, and the other end of the refrigeration element 4 is placed on a cross bar part of the supporting member 51, such that the other end of the refrigeration element 4 is supported by the cross bar part of the supporting member 51, and a vertical bar part of the supporting member 51 matches up with the barrier 3 to clamp the refrigeration element 4. The fixing member 52 is fixedly connected to the box body 1. The telescopic adjusting component is respectively connected to the supporting member 51 and the fixing member 52 to control the supporting member 51 to horizontally move with respect to the fixing member 52.

In this embodiment, when it is required to install the refrigeration element 4 on the top of the component to be cooled 2, the telescopic adjusting component may be controlled to retract first, then the air inlet of the refrigeration element 4 is aligned with the corresponding through hole 31, and next the telescopic adjusting component is adjusted, such that the telescopic adjusting component matches up with the barrier 3 to clamp the refrigeration element 4 in a middle, to fix the refrigeration element 4.

Further, as shown in FIG. 5, a baffle 56 may be respectively connected to each of two sides of the supporting member 51. When the other end of the refrigeration element 4 is placed on the cross bar part of the supporting member 51, the other end of the refrigeration element 4 is positioned between the two baffles 56, such that two sides of the other end of the refrigeration element 4 are limited by the two baffles 56 to avoid longitudinal shift of the refrigeration element 4 when it is shaken.

Various embodiments may be provided for the telescopic adjusting component. In a first embodiment, the telescopic adjusting component may include a slide bar 53 and a spring 54. The slide bar 53 is slidably connected to the fixing member 52, and one end of the slide bar 53 is connected to the supporting member 51. The spring 54 is sleeved on the slide bar 53 and is positioned between the supporting member 51 and the fixing member 52.

In this embodiment, the slide bar 53 may be a T-shaped bar, where a larger head end of the slide bar 53 is positioned in the fixing member 52 to prevent the slide bar 53 from breaking away from the fixing member 52. The other end of the slide bar 53 is connected to the supporting member 51, such that the supporting member 51 may slide with respect to the fixing member 52, and the supporting member 51 may abut against the other end of the refrigeration element 4 under the action of an elastic force of the spring 54 to connect the other end of the refrigeration element 4.

It is to be noted that when one slide bar 53 is provided, the cross section of the slide bar 53 should be a non-circular cross section. For example, the cross section of the slide bar 53 may be square, pentagonal or the like. In this way, the supporting member 51 can be prevented from rotating about the slide bar 53, and the supporting member 51 can be guaranteed to be in a horizontally telescopic state all along.

When a plurality of slide bars 53 are provided, the plurality of slide bars 53 can restrict the supporting member 51 and prevent the supporting member 51 from being turned over. Therefore, the cross-sectional shape of the supporting member 51 does not need to be considered, and the cross section of the supporting member 51 may be arbitrary shape. The plurality of slide bars 53 are arranged in a preset array, and the spring 54 is sleeved on each of the slide bars 53. The preset array may be a rectangular array, a ring array or a linear array, etc.

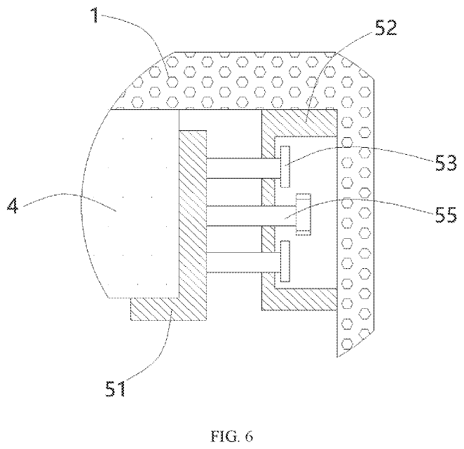

In a second embodiment, referring to FIG. 6, the telescopic adjusting component includes an adjusting screw rod 55. The adjusting screw rod 55 is in threaded connection with the fixing member 52, and one end of the adjusting screw rod 55 passes through the fixing member 52 and is movably connected to the supporting member 51. Thus, a user can control the supporting member 51 to horizontally move with respect to the fixing member 52 by rotating the adjusting screw rod 55.

In practical use, the telescopic adjusting component may also include a slide bar 53 slidably connected to the fixing member 52, where one end of the slide bar 53 is connected to the supporting member 51. Thus, the slide bar 53 can support the supporting member 51 to avoid screw thread damage between the slide bar 53 and the supporting member 51. Furthermore, the adjusting screw rod 55 matches up with the slide bar 53 to prevent the supporting member 51 from rotating around an axis of the adjusting screw rod 55, thereby ensuring that the supporting member 51 is in the horizontally telescopic state all along, making it convenient for use.

In an implementable embodiment, referring to FIG. 1 again, a cushion space 12 is also provided in the box body 1. The cushion space 12 is communicated with the accommodating cavity 11 through a switch gate. The cushion space 12 may be used as a transition space in which the accommodating cavity 11 is communicated with outside, to prevent dust from entering the accommodating cavity 11 and to reduce emission of cold air in the accommodating cavity 11.

Based on the same inventive concept, the present disclosure also provides a container data center, which at least includes the above-mentioned rooftop refrigeration system. The box body 1 is a container, and the component to be cooled 2 is a server unit.

As can be seen, according to the technical solutions provided by the present disclosure, the barrier is arranged on the top surface of the component to be cooled, the barrier and the component to be cooled divide the accommodating cavity into the hot runner and the cold runner, and a plurality of through holes are provided on the side surface of the barrier. Air inlets of the refrigeration elements are communicated with the through holes one to one, and air outlets of the refrigeration elements are communicated with the cold runner. The refrigeration element discharges cold air into a cold channel, the cold air passes through the component to be cooled for heat exchange to form hot air flowing into a hot channel, and the hot air in the hot channel enters the refrigeration element through the through hole for heat exchange. In this way, a refrigeration cycle is formed, to ensure refrigeration effects of the component to be cooled. Furthermore, the refrigeration element is positioned above the component to be cooled, which can increase the number of the servers arranged in the container and thus increase computing capacity of the container data center compared with the existing mode where the refrigeration elements and the servers are arranged at intervals side by side.

Furthermore, the two sides of the supporting member may be respectively connected to a baffle. When the other end of the refrigeration element is placed on the cross bar part of the supporting member, the other end of the refrigeration element is positioned between the two baffles, such that two sides of the other end of the refrigeration element are limited by the two baffles, thus avoiding the longitudinal shift of the refrigeration element when it is shaken and ensuring stability of operation of the device.

The examples set forth above are only illustrated as preferred examples of the present disclosure, and are not intended to limit the present disclosure. All modifications, equivalent substitutions and improvements made within the spirit and principles of the present disclosure shall fall within the protection scope of the present disclosure.

What is claimed is:

1. A rooftop refrigeration system at least comprising a box body (1), a component to be cooled (2), a barrier (3), and a refrigeration element (4); wherein
the box body (1) is provided with an accommodating cavity (11), and the component to be cooled (2), the barrier (3) and the refrigeration element (4) are installed in the accommodating cavity (11);
the barrier (3) is arranged on a top surface of the component to be cooled (2), the barrier (3) and the component to be cooled (2) divide the accommodating cavity (11) into a cold runner (111) and a hot runner (112), and a plurality of through holes (31) are provided on a side surface of the barrier (3); and
a plurality of the refrigeration elements (4) are provided, air inlets of the plurality of refrigeration elements (4) are communicated with the plurality of through holes (31) one to one, and air outlets of the plurality of refrigeration elements (4) are communicated with the cold runner (111).

2. The rooftop refrigeration system according to claim 1, wherein one end of the refrigeration element (4) is placed on the top surface of the component to be cooled (2), and other end of the refrigeration element (4) is connected to the box body (1) through a supporting mechanism (5) to install the refrigeration element (4) above the component to be cooled (2).

3. The rooftop refrigeration system according to claim 2, wherein the supporting mechanism (5) at least comprises a supporting member (51), a fixing member (52), and a telescopic adjusting component;
a cross section of the supporting member (51) is L-shaped, and the other end of the refrigeration element (4) is placed on a cross bar part of the supporting member (51);
the fixing member (52) is fixedly connected to the box body (1); and
the telescopic adjusting component is respectively connected to the supporting member (51) and the fixing member (52) to control the supporting member (51) to horizontally move with respect to the fixing member (52).

4. The rooftop refrigeration system according to claim 3, wherein the telescopic adjusting component comprises a slide bar (53) and a spring (54);
the slide bar (53) is slidably connected to the fixing member (52), and one end of the slide bar (53) is connected to the supporting member (51); and
the spring (54) is sleeved on the slide bar (53), and the spring (54) is positioned between the supporting member (51) and the fixing member (52).

5. The rooftop refrigeration system according to claim 4, wherein number of the slide bar (53) is one, and a cross section of the slide bar (53) is a non-circular cross section.

6. The rooftop refrigeration system according to claim 4, wherein a plurality of the slide bars (53) are provided, the plurality of slide bars (53) are arranged in a preset array, and the spring (54) is sleeved on each of the plurality of slide bars (53).

7. The rooftop refrigeration system according to claim 3, wherein the telescopic adjusting component comprises an adjusting screw rod (55);
the adjusting screw rod (55) is in threaded connection with the fixing member (52), and one end of the adjusting screw rod (55) passes through the fixing member (52) and is movably connected to the supporting member (51).

8. The rooftop refrigeration system according to claim 7, wherein a baffle (56) is respectively connected to each of two sides of the supporting member (51); and
when the other end of the refrigeration element (4) is placed on the cross bar part of the supporting member (51), the other end of the refrigeration element (4) is positioned between the two baffles (56).

9. The rooftop refrigeration system according to claim 1, wherein a cushion space (12) is further provided in the box body (1); and
the cushion space (12) is communicated with the accommodating cavity (11) through a switch gate.

10. A container data center at least comprising a rooftop refrigeration system; wherein the rooftop refrigeration system at least comprises a box body (1), a component to be cooled (2), a barrier (3), and a refrigeration element (4); wherein
the box body (1) is provided with an accommodating cavity (11), and the component to be cooled (2), the barrier (3) and the refrigeration element (4) are installed in the accommodating cavity (11);
the barrier (3) is arranged on a top surface of the component to be cooled (2), the barrier (3) and the component to be cooled (2) divide the accommodating cavity (11) into a cold runner (111) and a hot runner (112), and a plurality of through holes (31) are provided on a side surface of the barrier (3); and
a plurality of the refrigeration elements (4) are provided, air inlets of the plurality of refrigeration elements (4) are communicated with the plurality of through holes (31) one to one, and air outlets of the plurality of refrigeration elements (4) are communicated with the cold runner (111); and
the box body (1) is a container, and the component to be cooled (2) is a server unit.

11. The container data center according to claim 10, wherein one end of the refrigeration element (4) is placed on the top surface of the component to be cooled (2), and other end of the refrigeration element (4) is connected to the box body (1) through a supporting mechanism (5) to install the refrigeration element (4) above the component to be cooled (2).

12. The container data center according to claim 11, wherein the supporting mechanism (5) at least comprises a supporting member (51), a fixing member (52), and a telescopic adjusting component;
a cross section of the supporting member (51) is L-shaped, and the other end of the refrigeration element (4) is placed on a cross bar part of the supporting member (51);
the fixing member (52) is fixedly connected to the box body (1); and
the telescopic adjusting component is respectively connected to the supporting member (51) and the fixing member (52) to control the supporting member (51) to horizontally move with respect to the fixing member (52).

13. The container data center according to claim 12, wherein the telescopic adjusting component comprises a slide bar (53) and a spring (54);
the slide bar (53) is slidably connected to the fixing member (52), and one end of the slide bar (53) is connected to the supporting member (51); and
the spring (54) is sleeved on the slide bar (53), and the spring (54) is positioned between the supporting member (51) and the fixing member (52).

14. The container data center according to claim 13, wherein number of the slide bar (53) is one, and a cross section of the slide bar (53) is a non-circular cross section.

15. The container data center according to claim 13, wherein a plurality of the slide bars (53) are provided, the plurality of slide bars (53) are arranged in a preset array, and the spring (54) is sleeved on each of the plurality of slide bars (53).

16. The container data center according to claim 12, wherein the telescopic adjusting component comprises an adjusting screw rod (55);
the adjusting screw rod (55) is in threaded connection with the fixing member (52), and one end of the adjusting screw rod (55) passes through the fixing member (52) and is movably connected to the supporting member (51).

17. The container data center according to claim 16, wherein a baffle (56) is respectively connected to each of two sides of the supporting member (51); and
when the other end of the refrigeration element (4) is placed on the cross bar part of the supporting member (51), the other end of the refrigeration element (4) is positioned between the two baffles (56).

18. The container data center according to claim 10, wherein a cushion space (12) is further provided in the box body (1); and
the cushion space (12) is communicated with the accommodating cavity (11) through a switch gate.
